(19) United States
(12) Patent Application Publication
(10) Pub. No.: US 2026/0087217 A1
(43) Pub. Date: Mar. 26, 2026

(54) METHOD FOR DETERMINING COMPUTING HARDWARE ARCHITECTURES BY DYNAMICALLY CONTROLLING A PLURALITY OF EVALUATION TOOLS

(71) Applicant: COMMISSARIAT À L'ENERGIE ATOMIQUE ET AUX ENERGIES ALTERNATIVES, PARIS (FR)

(72) Inventors: Lilia ZAOURAR, GIF SUR YVETTE (FR); Jean-Marc PHILIPPE, GIF SUR YVETTE (FR)

(21) Appl. No.: 19/331,931

(22) Filed: Sep. 17, 2025

(30) Foreign Application Priority Data
Sep. 26, 2024 (FR) 2410314

(51) Int. Cl. G06F 30/33

(52) U.S. Cl. CPC G06F 30/33

(57) ABSTRACT

A method is proposed for determining a hardware architecture of an integrated circuit, includes: determining a plurality of candidate architecture configurations with different hierarchical scales, each configuration being defined by a number of configuration instances; evaluating the configurations using multi-level evaluation tools, the evaluation of a configuration by a tool including iterative execution such that each iteration corresponds to the evaluation of one of the instances of the configuration; the evaluation providing an output relating to the execution of the evaluation tools; and determining at least one optimized configuration based on the output. The method includes interrupting at least one iterative execution of a tool associated with a configuration, in response to the confirmation of a stop criterion defined such that the total number of iterations of the iterative execution is strictly less than the number of instances of the candidate configuration.

### CROSS-REFERENCE TO RELATED APPLICATION

This application claims priority to foreign French patent application No. FR 2410314, filed on Sep. 26, 2024, the disclosure of which is incorporated by reference in its entirety.

### FIELD OF THE INVENTION

The present invention generally relates to electronic systems, and in particular to a method for determining computing hardware architectures by dynamically controlling a plurality of evaluation tools.

### BACKGROUND

Computing hardware architectures are conventionally used as basic elements for designing systems-on-chip.

A System-on-Chip, also called SoC, corresponds to a complete system embedded on an integrated circuit that comprises a multitude of electrical or electronic components. Such an integrated circuit implements characteristic functionalities associated with a specific application or application domain, as well as generic elements, such as processor cores, memory elements or even input/outputs. An integrated circuit includes a hardware device that is generally associated with software configured to control the hardware device and, in particular, to implement the characteristic functionalities. The hardware device comprises, particularly for “high-performance” SoCs, a multi-core hardware architecture (i.e., made up of several computing cores) and is produced from assembled hardware bricks. The design of the hardware device includes the development of the hardware architecture of the different basic bricks and their configuration using known Computer-Aided Design or CAD tools, according to a design flow. A design flow includes a set of steps implemented using a large number of tools. Such tools enable the actual design (for example, the transformation of a high-level architecture description into a lower-level description) to be completed, as well as the evaluation of possible architecture configuration cases. Such tools are also used to validate the complete design of an SoC circuit.

With the increasing complexity of integrated circuits, such a design flow results in an increase in the design space for exploration, which can result in multiple iterations for each stage of the design flow, increased complexity of the tools and difficulties in linking the different tools, as well as an increase in the cost of the necessary resources (computing, human, etc.).

Different design methods and tools have been proposed in an attempt to improve the design flow of computing hardware architectures. Known methods use manual or semi-automatic design flows, using different static or dynamic evaluation tools and simulators to explore the design space and defined architecture configurations by applying an optimization algorithm, as described, for example, in the article entitled, “An Automatic Design Space Exploration Framework for Multicore Architecture Optimizations”, by H. Calborean, et al., 9th RoEduNet, vol. 14, 2010, or as described, for example, in the article entitled, “Multilevel simulation-based co-design of next generation HPC microprocessors”, by L. Zaourar et al., International Workshop PMPBS (PMBS), Super Computing, St. Louis, United States, 2021.

However, such methods do not allow fully automatic or dynamic control of the different simulation tools in a design flow, and therefore do not allow optimal use of a wide range of parameters and sub-parameters in architectural configurations to be evaluated. Consequently, the known methods do not allow the best possible configurations to be determined from the available evaluation tools. Furthermore, the inflexibility in controlling simulation tools in such methods does not allow a multi-level view of the design of an integrated circuit to be supported.

Thus, a requirement exists for a method that is capable of optimizing the determination of the computing hardware architectures to be used for the multi-level and multi-scale design of an integrated circuit.

### SUMMARY OF THE INVENTION

To this end, a method for determining a hardware architecture of an integrated circuit is proposed. The determination method is computer-implemented and comprises:
determining a plurality of candidate architecture configurations corresponding to different hierarchical scales of the architecture of the integrated circuit to be designed, each candidate configuration being defined by a set of configuration elements comprising at least one configuration element, each candidate configuration being associated with a number of instances of the candidate configuration, each configuration instance corresponding to a combination of values of the configuration elements;
evaluating the plurality of candidate configurations using at least two evaluation tools selected from among a plurality of evaluation tools capable of performing a multi-level analysis of architecture design, each candidate configuration being evaluated by at least one of the selected evaluation tools, the evaluation of a candidate configuration by an evaluation tool comprising the iterative execution of the evaluation tool in order to evaluate one or more instances of said candidate configuration, the iterative execution of the tool comprising a number of iterations, each iteration corresponding to the evaluation of an instance of the candidate configuration by the evaluation tool, the evaluation step providing an evaluation output relating to the execution of each of said at least two selected evaluation tools;
determining at least one optimized configuration of a hardware architecture of an integrated circuit based on said evaluation output.

The method comprises automatic control of the at least two selected evaluation tools, comprising controlling at least one iterative execution of each evaluation tool for evaluating at least one candidate configuration.

The method further comprises interrupting the iterative execution of an evaluation tool associated with a candidate configuration, in response to the confirmation of a stop criterion, the stop criterion being defined such that the total number of iterations of the iterative execution is strictly less than the number of instances of the candidate configuration.

In some embodiments, the evaluation step can comprise resuming the iterative execution of a selected evaluation tool after an interruption, in response to the confirmation of a resumption criterion defined such that the total number of iterations of the iterative execution is strictly greater than the number of iterations implemented until the interruption.

Advantageously, the plurality of candidate configurations comprises at least one first candidate configuration and one second candidate configuration, the second candidate configuration being a sub-configuration of the first candidate configuration, the selected evaluation tools comprising at least one first evaluation tool for evaluating the first candidate configuration and one second evaluation tool for evaluating the second candidate configuration.

The stop criterion for interrupting the iterative execution of the second evaluation tool can be confirmed in response to the interruption of the iterative execution of the first evaluation tool.

In some embodiments, the evaluation of an instance of a candidate configuration by an evaluation tool can comprise:
an analysis of an instance of the architecture configuration by the evaluation tool in response to the reception of input quantity values associated with the configuration instance; and
determining a set of output quantity values relating to the result of the analysis of the configuration instance by the evaluation tool.

Advantageously, the evaluation step can comprise, for each candidate configuration to be evaluated, the conversion of at least a portion of the candidate configuration into input quantity values and the generation of an input file associated with one of the evaluation tools selected so as to evaluate the candidate configuration, the input file comprising the input quantity values.

In some embodiments, the plurality of candidate configurations can comprise at least one first candidate configuration and one second candidate configuration, the selected evaluation tools comprising at least one first evaluation tool for evaluating the first candidate configuration and one second evaluation tool for evaluating the second candidate configuration. Each iteration of an iterative execution of an evaluation tool can provide at least one output quantity value, the iterative execution of the first evaluation tool for evaluating the first candidate configuration comprising, in response to an iterative execution of the first evaluation tool, storing the at least one output quantity value, and triggering at least one iterative execution of the second evaluation tool for evaluating the second candidate configuration.

According to some embodiments, at least one input quantity value of the input file of the second evaluation tool can be defined based on the conversion of the at least one stored output quantity value.

Advantageously, the evaluation step can comprise simultaneously triggering at least one iterative execution of at least two of the selected evaluation tools.

In some embodiments, the stop criterion can be defined as a function of an evaluation of at least one objective and/or constraint function relating to at least one optimization criterion, the at least one optimization criterion being selected from among a computing performance criterion, an energy consumption criterion and/or a surface area criterion of the integrated circuit to be designed.

The stop criterion can be defined as a function of the execution time of at least one of the iterative executions of a given evaluation tool, the stop criterion being met if the execution time reaches a predefined maximum execution time.

An evaluation tool from the plurality of evaluation tools can be an evaluation tool selected from among an architecture configuration simulator, an architecture compilation tool, a consumption evaluation tool, a tool based on the use of a database, and a tool based on the use of a memory of candidate configuration data.

A further aim of the invention is an integrated circuit hardware architecture obtained by implementing the determination method.

The invention further provides a method for designing an integrated circuit comprising an implementation of an integrated circuit based on the integrated circuit hardware architecture.

The invention also provides a computer program product comprising programming code instructions capable of being computer-implemented, the computer being capable of implementing the method for determining a hardware architecture of an integrated circuit.

The method for determining computing hardware architectures according to the embodiments of the invention allows the determination of the computing hardware architectures to be used in the design of an integrated circuit to be optimized. In particular, the method allows efficient and automatic optimization of the evaluation (or estimation) of the hardware architecture configurations to be analyzed.

The embodiments of the invention thus provide a fast, flexible and efficient solution for determining complex system-on-chip architecture configurations. Such a solution has the advantage of being “multi-objective” and “multi-level”, i.e., it allows optimization, on a co-simulation or co-emulation, with simulators running either simultaneously or one after the other, in the same evaluation of one or more architecture configurations. This solution also has the advantage of being “multi-scale”, in that it is applicable on different scales in the integrated circuit architecture (it is equally applicable to the complete system, to the system architecture including the interconnections between the basic elements, or even to the microarchitecture of the basic elements of the integrated circuit). The evaluation of the architecture configurations to be analyzed can be carried out based on the executions and different combinations of these diverse and varied evaluation tools, which can be functional or extra-functional, for example.

This results in a non-intrusive solution adapted to different existing methods for conventional circuit design flows (for example, for RTL (Register Transfer Level) code generation, logic synthesis, placement and routing, etc.). In particular, the method for determining computing hardware architectures according to the embodiments can be adapted to any design flow. Such a method does not require any modification of the steps usually implemented in a conventional circuit design flow and allows the evaluation phases in the different steps of the method to be improved. Furthermore, such a method requires minimal confidential information from a conventional design flow, such as information from the RTL code.

### BRIEF DESCRIPTION OF THE DRAWINGS

Further features, details and advantages of the invention will become apparent upon reading the description, which is provided with reference to the accompanying drawings that are provided by way of an example.

FIG. 1 is a flowchart showing the steps of the method for determining integrated circuit hardware architectures, according to embodiments of the invention.

FIG. 2 is a table showing lists of sets of parameters and sub-parameters to be optimized in an integrated circuit architecture, according to embodiments of the invention.

FIG. 3 is a flowchart showing the functional blocks associated with the evaluation step of the method for determining integrated circuit hardware architectures, according to embodiments of the invention.

FIG. 4 is a flowchart showing sub-steps associated with the evaluation step of the method for determining integrated circuit hardware architectures, according to embodiments of the invention.

FIG. 5 is a flowchart showing sub-steps associated with the evaluation step of the method for determining integrated circuit hardware architectures, according to embodiments of the invention.

FIG. 6 is a diagram showing an overall structure of an integrated circuit hardware architecture design flow, according to embodiments of the invention.

### DETAILED DESCRIPTION

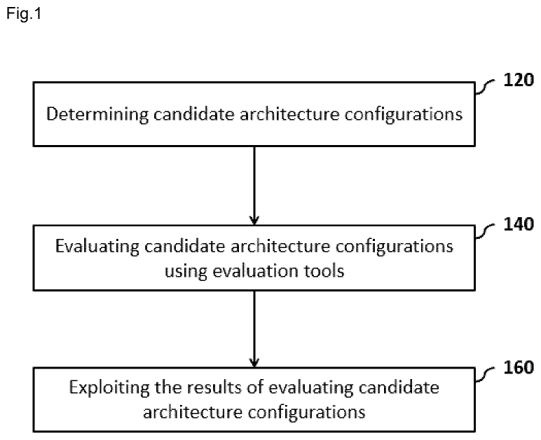

FIG. 1 shows a method for determining an integrated circuit hardware architecture, according to some embodiments of the invention.

The integrated circuit hardware architecture that is determined by such a method allows a hardware description file for an integrated circuit to be generated (for example, an SoC). The hardware description file of the integrated circuit can be a Python script describing the different blocks of the circuit, or can be written in a hardware description language, for example, and without limitation, in VHDL or Verilog language. Such a hardware description file then will be used to design the integrated circuit according to an existing integrated circuit design method. The integrated circuit is capable of performing all types of computations, and in particular complex computations.

The integrated circuit can be used or defined for many different applications and technical fields. The integrated circuit can be used, for example, and without limitation, in telecommunications systems, imaging systems, industrial systems (such as cybersecurity systems or systems associated with manufacturing processes, for example), in systems specific to the banking or fiscal field, or in computing systems, such as high-performance computing (HPC) systems or embedded systems (such as avionics or automotive systems), etc.

As shown in FIG. 1, the method for determining integrated circuit hardware architectures comprises an initial step 120 of determining a plurality of N candidate architecture configurations Gₙ of the integrated circuit (also simply called “candidate configurations”). The index “n” associated with the different generated candidate configurations is thus an integer ranging between 1 and N, and the value of N is an integer that is greater than or equal to 2. The candidate configurations are particularly determined based on a multi-criteria hardware architecture exploration (or design) space.

In step 140 of the design method, the candidate configurations Gₙ are evaluated based on a plurality M of configuration evaluation tools Oₘ The index “m” associated with the different evaluation tools Om that are used is thus an integer ranging between 1 and M, and the value of M is an integer that is greater than or equal to 2. In particular, each candidate configuration Gₙ is evaluated based on the execution of at least one evaluation tool Om selected from among the plurality of M evaluation tools Oₘ.

As used herein, the term “evaluation tool” refers to any computer tool, or a sub-part of a computer tool, configured to analyze an architecture configuration, with the analysis of the configuration corresponding to an evaluation of the configuration.

An evaluation tool can be a simulation or compilation tool.

In step 160 of the design method, the results of the evaluation of the candidate configurations Gₙ are used to determine one or more optimized configurations Gₒₚₜ Of the computing architecture according to various optimization criteria. The use of optimized configurations Gₒₚₜ allows the desired hardware architecture of the considered integrated circuit to be determined.

The method (also called “estimation method” or “design method”) for determining an integrated circuit hardware architecture, according to the embodiments of the invention, thus allows an integrated circuit hardware architecture to be determined that is based on the exploration space and that is adapted to the efficient execution of complex or specific computations by the integrated circuit.

Advantageously, the method for designing integrated circuit hardware architectures can comprise a plurality of iterations, called “optimization iterations”, of steps 120, 140 and 160. In particular, for each optimization iteration of the design method, the number N of generated candidate configurations and the number M and the nature of the evaluation tools that are used can differ.

The exploration space for multi-criteria hardware architectures corresponds to a representation (also called a “mathematical representation”) of a problem optimizing the design of the architecture. The exploration space includes a set of elements for defining (or describing or modelling) an integrated circuit hardware architecture. In particular, such a set of elements can include parameters of the integrated circuit to be designed (for example, structural parameters related to the components and/or resources of the circuit), circuit optimization objectives defined by objective functions of the integrated circuit to be designed, and/or constraint functions of the integrated circuit to be designed. An objective function refers to a function that defines an optimization criterion (i.e., a criterion for determining the best solution to an optimization problem). Examples of objective functions include, for example, performance and/or energy consumption and/or the sizing of the circuit.

The integrated circuit can be, for example, a heterogeneous high-performance computing processor comprising a plurality of computing cores and/or computing accelerators, and different constituent elements (or integrated circuit components such as memories). In such an example, the parameters of the integrated circuit to be designed can include the types of computing cores, the number of computing cores for each type of core, the memory hierarchy, the bandwidth and pre-reading (or pre-loading) of the memories, and/or the interconnection between the different computing resources (for example, a network-on-chip, or NoC), etc.

In some embodiments, the objective functions of the integrated circuit to be designed can include, for example, maximizing the computing performance of the integrated circuit, minimizing the energy consumption of the integrated circuit, and/or minimizing the surface area (or the size) of the integrated circuit. In particular, the computing performance can be associated, for example, with a temporal datum such as latency or the execution frequency of the computations, the performance also can be related to the peak computing power, for example, the number of computing elements in the integrated circuit and their size, and/or to the memory footprint of the hardware architecture, for example, the number of storage elements in the integrated circuit and their size.

The constraints of the integrated circuit to be designed can be, for example, design constraints relating to the predetermined parameters of the circuit and/or objectives, or even known physical constraints.

The exploration space can include a set P of parameters to be optimized (also called parameters to be explored or decision variables) of the integrated circuit to be designed.

For some of the parameters to be optimized from the set P, the exploration space can also include a set Lₚ of sub-parameters [symbol] _{pq} to be optimized, associated with the considered parameter of the integrated circuit to be designed. The exploration space can also include one or more sets L_{pq} of sub-parameters associated with any sub-parameter of a set Lₚ, for example.

Thus, the exploration space, comprising the set P and different sets denoted L, can be structured hierarchically as a function of the dependencies between parameters and sub-parameters. The set P and/or the one or more sets L can be implemented, for example, in the form of matrices, tables, lists or vectors. The exploration space can also include a set F of objective functions and/or constraint functions of the integrated circuit to be designed.

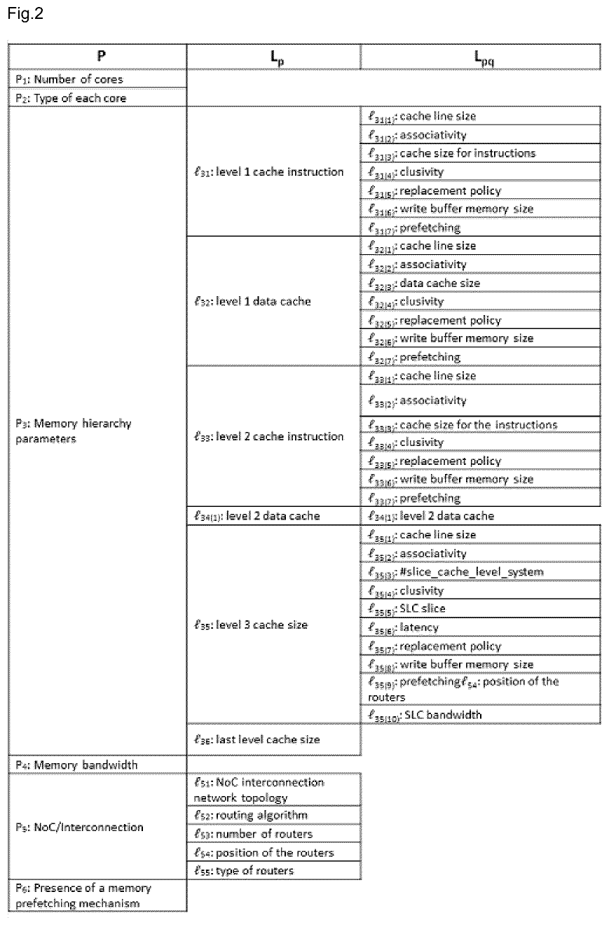

By way of a non-limiting example, FIG. 2 shows a table including lists of sets P and L, for parameters Pp and sub-parameters [symbol] _{pq} to be optimized, for an integrated circuit comprising a plurality of computing cores.

As illustrated in FIG. 2, a list P thus can include the number of cores of the integrated circuit, the type of each core of the integrated circuit, the parameters of the cache memory hierarchy of the integrated circuit, the memory bandwidth of the integrated circuit, the type of NoC interconnection network of the integrated circuit, and/or the presence or absence of a memory preloading (or pre-reading) mechanism of the integrated circuit (also called memory prefetching), etc.

A list Lₚ can include, as for the list L₃ associated with the parameter “P₃: memory hierarchy parameters”, the following:
a cache instruction memory corresponding to a cache memory only storing instructions;
a data cache memory corresponding to a cache memory only storing data;
the size of the level 3 cache (or SLC (System Level Cache)); and/or
the size of the last level cache (or LLC (Last Level Cache)), etc.

A list Lₚ can include, as for the list L₅ associated with the parameter “P5: NoC/Interconnection” of the list P, a topology of the NoC interconnection network, a routing algorithm, a number of routers, and the position and/or the type of each router.

Similarly, for the sub-parameters “ [symbol] ₃₁: level 1 cache instruction”, “ [symbol] ₃₂: level 1 data cache”, or even “ [symbol] ₃₃: level 2 cache instruction” in the list L₃ associated with the parameter “P₃: memory hierarchy parameters”, for example, a list L_{pq} can include a certain number of sub-parameters. Such a list L_{pq} can include the cache line size, the associativity, the cache size for the data or the instructions, the clusivity, the replacement policy, the write buffer memory size, and/or the prefetcher, etc. For the sub-parameter “ [symbol] ₃₅: the level 3 cache size” of the L₃ list, for example, a list L_{pq} can include a system-level cache slice (or #SLC slice), SLC slice parameters (or SLC slice), the latency and/or the SLC bandwidth, etc.

Each candidate configuration Gₙ is associated with a set of configuration instances (also called “configuration versions”). A candidate configuration is defined by a set of configuration elements (comprising at least one configuration element), each of which can assume:
either a Single Value;
or a plurality of possible values, in which case the candidate configuration has several configuration instances, each corresponding to the set of configuration elements defined for the candidate configuration, but with different combinations of configuration element values for each configuration instance, with the values of the elements being selected from among the possible values associated with the different elements.

As used herein, the term “configuration element” (or “element of a configuration”) refers to a parameter relating to the set P, or to a sub-parameter relating to the set Lₚ or to any other set L_{pq}. Each element of a candidate configuration Gₙ can be associated with a single value or with a plurality of possible values (in which case the configuration element is a “variable”). A “value” associated with a configuration element can be, for example, of the numerical data type or of the character string type.

For example, and without limitation, an element of a candidate configuration Gₙ can be associated with the parameter P₁, relating to the number of cores in the integrated circuit. In this case, the configuration element can be the number of cores and can be associated with a single integer value. In this simplified example, assuming that the candidate configuration has a single configuration element, the candidate configuration has a single configuration instance corresponding to the single possible value for the considered configuration element.

As a variant, the configuration element associated with the parameter P₁ could correspond to the number of cores but be associated with a list of possible core numbers (i.e., possible values). In this simplified example, assuming that the candidate configuration has a single configuration element, the candidate configuration has multiple configuration instances, each corresponding to one of the different possible values for the considered configuration element.

A candidate configuration Gₙ is thus associated with a number Hₙ of configuration instances, denoted Gₙₕ, which are different variations of the candidate configuration with different combinations of values for the configuration elements (from among the possible values defined for each configuration element). The index “h” associated with the different configuration instances is an integer ranging between 1 and Hₙ, and the value of Hₙ is greater than or equal to 1.

In the event that a candidate configuration Gₙ includes a number Hₙ equal to 1, the candidate configuration Gₙ is only made up of a single configuration instance Gₙ₁, and each element of the candidate configuration Gₙ is associated with a single value.

In the event that a candidate configuration Gₙ includes a number Hₙ of instances that is strictly greater than 1, the candidate configuration Gₙ is made up of a plurality of configuration instances Gₙₕ, and at least one element of the candidate configuration Gₙ is associated with a plurality of possible values. Each instance Gₙₕ of the same candidate configuration Gₙ therefore corresponds to the candidate configuration Gₙ defined by its set of configuration elements, but with different combinations of values for the configuration elements from one instance to another.

For example, and without limitation, a candidate configuration can include a set of elements each corresponding to a unique value (i.e., characteristic of the represented parameter or sub-parameter), and an element associated with a plurality of X possible values. The number of instances of such a candidate configuration then can be equal to X.

Thus, in some embodiments, a candidate configuration Gₙ can include a first configuration instance Gₙ₁ and a second configuration instance Gₙ₂. The first and second instances can include the same set of elements corresponding to the same set unique values. The first and second instances differ in that the first instance Gₙ₁ includes a first value of a variable and the second instance Gₙ₂ includes a second value of this variable, for the same element of the candidate configuration Gₙ. The first and the second value of this variable are distinct from each other.

A candidate configuration Gₙ, determined in step 120 of the design method (during a given optimization iteration of the method, for example), can include configuration elements corresponding, for example, to a sub-set of elements P, some parameters of which are defined according to a set value, and/or sub-sets of elements L, some sub-parameters of which are also defined according to a set value. Advantageously, a candidate configuration Gₙ can also include one or more configuration elements corresponding to variables to be evaluated, for one or more parameters Pₚ and/or sub-parameters [symbol] _{pq} (i.e., list L corresponding to Lₚ or L_{pq}). In this case, a configuration element, each corresponding to a plurality of values to be evaluated, is defined according to a given (or determined) list, denoted V. For example, and without limitation, an element of a candidate configuration Gₙ can be defined by a list V of discrete values defined in step 120 of the design method.

The candidate configurations Gₙ thus can be determined in step 120 of the determination method by applying an optimization algorithm performing an operational search applied to the architecture exploration space. An operational search (also called “combinatorial optimization” or “decision support”) can be applied in order to analyze complex situations and/or to determine one or more solutions to the problem of designing a hardware architecture to be optimized. An optimization algorithm can be any algorithm or mathematical model capable of determining different decision variables (i.e., parameters and sub-parameters) and different objective and/or constraint functions of an exploration space. Thus, each candidate configuration Gₙ (or configuration instance Gₙₕ) corresponds to a sub-set of the architecture exploration space.

In particular, each candidate configuration Gₙ of the set of generated candidate configurations is an architecture configuration that is different from each of the other generated configurations, during the same optimization iteration and during previous optimization iterations.

Advantageously, the architecture “scale” (also called the “hierarchical level” of the architecture) relative to the determined candidate configurations can be different between at least two of the N configurations generated in step 120, during the same optimization iteration of the determination method. In other words, at least two configurations generated in step 120 can have two different architecture scales.

As used herein, the term “scale” (or the term “architecture scale”), associated with a candidate configuration, refers to the “hierarchical scale” relative to the hierarchical content (parameters and/or sub-parameters) of the architecture characterizing the considered configuration.

As used herein, the term “level” (also called “design level” or “flow level”) for its part refers to the architecture description in terms of the design flow. For example, for the circuit to be designed, the term “level” refers to the “system level”, to the “behavioral level”, to the “RTL level”, to the “logic level”, to the “physical level”, etc. Throughout the remainder of the description, the term “level” will be notably used in relation to the analysis of one or more candidate configurations considered by a specific evaluation tool.

A “candidate configuration”, which is defined according to a hierarchical scale and relates to an optimization iteration, can correspond to a “candidate sub-configuration” of a candidate configuration, defined according to another hierarchical scale and relating to any previous optimization iteration and/or to the same optimization iteration. Thus, a candidate sub-configuration can include all the parameters and/or sub-parameters, as well as their associated values, of a considered candidate configuration, defined according to a given hierarchical scale. However, a candidate sub-configuration can correspond to a “lower” scale in the hierarchical content of the architecture, and can include additional parameters and/or sub-parameters associated with given values.

For example, and without limitation, initial optimization iterations of the design method can be performed in order to determine one or more initial candidate configurations associated with the evaluation of certain parameter values Pₚ. One or more subsequent iterations then can be performed in order to determine one or more candidate configurations, derived from one or more candidate configurations evaluated during any previous optimization iteration, associated, for example, with the evaluation of certain values of sub-parameters [symbol] _{pq} from a list Lₚ. The method can continue in a similar manner by associating one or more subsequent candidate configurations with the evaluation of certain values of sub-parameters [symbol] _{pq} from a considered list L_{pq}.

In some embodiments, during the same optimization iteration, in step 120, a plurality of determined candidate configurations Gₙ can include a first candidate configuration G₁ and a second candidate configuration G₂, with the first candidate configuration and the second candidate configuration corresponding to two distinct hierarchical scales in the architecture of the integrated circuit to be designed. The first candidate configuration G₁ can include parameters and/or sub-parameters relating to a first hierarchical scale in the architecture of the integrated circuit to be designed, and the second candidate configuration G₂ can include parameters and/or sub-parameters relating to a second hierarchical scale in the architecture.

Advantageously, the second candidate configuration G₂ can correspond to a “candidate sub-configuration”of the first candidate configuration G₁.

In some embodiments, the evaluation of one or more candidate configurations Gₙ also can be associated with two distinct design levels relating to the architecture description in terms of the design flow of the integrated circuit to be designed. The evaluation of a first candidate configuration G₁ can correspond to an evaluation, according to a first description level, for example, on the system level of the architecture, and the evaluation of a second candidate configuration G₂ can correspond to an evaluation according to a second description level, for example, on the microarchitecture level of the integrated circuit to be designed. The first and the second level can also correspond to an RTL level and to a synthesis level, for example.

In some embodiments, the first candidate configuration G₁ can be associated with the evaluation of certain parameter values Pₚ, and the second candidate configuration G₂ can be associated with the evaluation of certain sub-parameter values [symbol] _{pq} from a list Lₚ. For example, the first candidate configuration G₁ can include at least:
a set value (p₂) associated with the parameter P₂ relating to the core type; and
a list of H₁ integers {p₁} associated with the parameter P₁ relating to the number of cores of the integrated circuit to be optimized.

The first candidate configuration G₁ thus includes a number H₁ of configuration instances, each associated with the same value p₂ and with one of the different possible values in the list {p₁}.

Each instance, from among the number H₁ of instances, represents a configuration with the same core type (p₂) for different numbers of determined cores. The evaluation of the first candidate configuration G₁ then corresponds to the evaluation of different numbers of cores {p₁} according to the same core type. The evaluation of the first candidate configuration G₁ can also correspond to a comparison of the results of the analysis of the instances as a function of the different numbers of cores {p₁} according to the same core type.

The second candidate configuration G₂ can include at least:
a set value (denoted p₃) associated with the parameter P₃ relating to the memory hierarchy parameter; and
a list of data H₂ associated with the parameter [symbol] ₃₁ of the integrated circuit to be optimized.

The second candidate configuration G₂ thus includes at least a number H₂ of instances representing a configuration with a given memory hierarchy parameter, and the evaluation of the second candidate configuration G₂ then corresponds to the evaluation of different values {p₃₁}. The evaluation of the second candidate configuration G₂ can also correspond to a comparison of the analysis results of the instances as a function of the different values {p₃₁}.

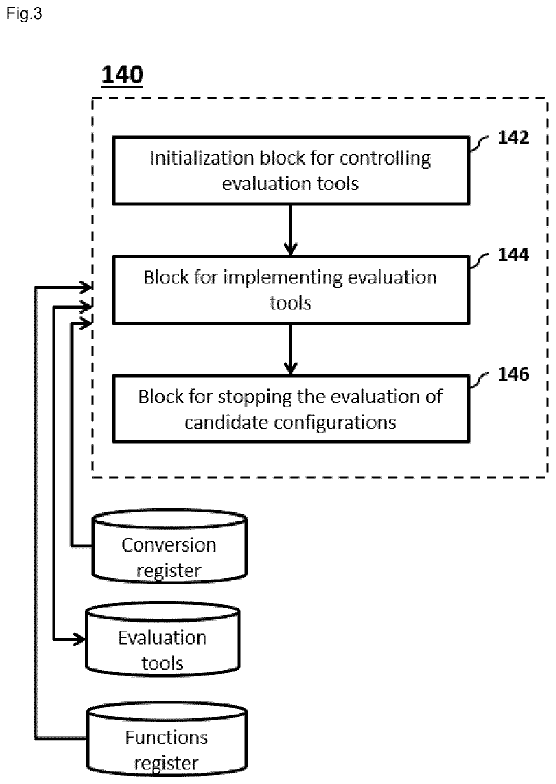

FIG. 3 illustrates the step 140 of evaluating the candidate configurations Gₙ of the determination method, according to some embodiments of the invention.

The evaluation step 140 comprises an initialization block 142 for controlling (also called managing) the execution of the evaluation tools Oₘ.

An evaluation tool Oₘ can be configured to receive a set of predefined input quantities Eₘ as input, and to deliver one or more output quantities Sₘ as output corresponding to the analysis results of the tool. For example, output quantities Sₘ can be traces from the evaluation tool Oₘ.

Advantageously, in order to be able to evaluate an instance of a candidate configuration Gₙ, an evaluation tool Oₘ therefore receives values for the different input quantities Eₘ, with these values being associated with the considered configuration instance.

In some embodiments, in response to the analysis of an instance of a given candidate configuration Gₙ, the evaluation tool Oₘ is capable of outputting one or more values of output quantities Sₘ corresponding to the evaluation (or analysis) results of the configuration instance. The number of input quantities Eₘ and/or of output quantities Sₘ depends on the evaluation tool Oₘ, and can also depend on the design level and/or the scale associated with the considered candidate configuration Gₙ.

For example, and without limitation, an evaluation tool Oₘ can be a simulator of functional instruction sets, a memory hierarchy simulator, a high-level architecture simulator, such as: VPSim, GEM5, Virtualizer or Vista, or RTL level, or ModelSim or Questa level, the DRAMSys or even DRAMPower open source computer tool specific to the memory hierarchy, or even tools such as Arm Fast Model, McPat, etc.

As a variant, an evaluation tool Oₘ can be, for example, an architecture synthesis tool such as the Synopsys “Design Compiler” tool, which provides more accurate and sophisticated results.

In the event that an evaluation tool Oₘ is of the VPSim simulator type, possible input values Eₘ for the VPSim simulator can be parameters related to the hardware architecture of the integrated circuit, such as the “number of cores” or the “type of cores”. In the event that an evaluation tool Oₘ is of the GEM5 simulator type, possible input values Eₘ for the GEM5 simulator can be parameters related to the microarchitecture of the integrated circuit, such as the sub-parameters associated with the microarchitecture of the cores (for example, the “data pre-reading”, “size and number of registers”sub-parameters, etc.).

An example of an output quantity Sₘ provided by an evaluation tool can be an estimate of the computing performance of the integrated circuit (in terms of the computation execution time), or even a result of the interconnection or memory access evaluations, expressed, for example, in terms of a number, of time or of energy consumption.

In the event that an evaluation tool Oₘ is of the VPSim simulator type, an output quantity Sₘ of the VPSim simulator can be the execution time of an application on a configuration or, more generally, another metric related to the architecture, such as the number of successful cache hits, or the number of cache misses, for example.

It should be noted that the evaluation tools Oₘ each can be associated with operating quantities, such as the execution time tₘ (or execution duration), or even an exploration time limit t_{max_m} (or maximum execution duration), for example, for the evaluation of a candidate configuration (or configuration instance) by the tool. The exploration time limit t_{max_m} can be associated with a predefined value and can notably affect the one or more values of the output quantities Sₘ associated with the tool.

In some embodiments, several evaluation tools Oₘ, which are associated with distinct operating quantities, can be provided in order to evaluate the same output quantity Sₘ. For example, a VPSim simulator and a GEM5 simulator can each provide an estimate of the performance of the computations of the integrated circuit. For the GEM5 simulator, the performance estimate can be obtained over a very long analysis time, thus slowing down the overall exploration of the configurations. For an evaluation tool Oₘ of the VPSim simulator type, the performance estimate can be obtained over a very short analysis time, thus accelerating the overall exploration of the configurations. A performance estimate delivered by the VPSim simulator can be considered less accurate (or more approximate) than an estimate delivered by the GEM5 simulator (which is considered to be a more detailed estimate). Other output quantities can be provided by a VPSim simulator and/or a GEM5 simulator, such as the number of hits on certain resources, the type of hit, etc.

The initialization block 142 can be configured to select (or choose or define), from among a set of available tools, the plurality of M evaluation tools Oₘ Such a selection can be performed as a function of tool selection conditions and/or of the candidate configurations Gₙ. The selection of an evaluation tool notably can be performed as a function of a considered design level and/or of the hierarchical scale relating to at least one of the N candidate configurations Gₙ, or each of them. In particular, an evaluation tool can be selected in order to analyze one or more candidate configurations, with the same scale or with different hierarchical scales, according to the same level or according to different design levels.

In some embodiments, the plurality of evaluation tools Oₘ can include at least one first evaluation tool O₁ and one second evaluation tool O₂, with the first and second evaluation tools being configured to analyze at least one, or each, of the candidate configurations with distinct scales and/or per distinct design levels.

In one embodiment, the first evaluation tool O₁ can be selected to analyze the first candidate configuration G₁ of the plurality of N generated configurations, while the second evaluation tool O₂ can be selected to analyze the second candidate configuration G₂.

The first evaluation tool O₁ can be adapted to analyze at least the configurations defined according to a first architecture scale, in accordance with a first design level. The second evaluation tool O₂ can be adapted to analyze at least the configurations defined according to a second architecture scale, in accordance with a second design level.

For example, and without limitation, the first evaluation tool O₁ can be the VPsim tool configured to evaluate architecture-related parameters such as the number of cores, the core types, etc. The second evaluation tool O₂ can be the GEM5 tool configured to evaluate the microarchitecture parameters (parameters of the NoC, memory hierarchy), or the ARM Fast model for evaluating the consistency protocol, etc.

The first evaluation tool O₁ and the second evaluation tool O₂ can be selected in response to the detection of the respective scales and/or levels of each of the evaluations of generated candidate configurations, G₁ and G₂. Such detection can correspond, for example, to the identification of the design level and/or of the hierarchical scale of a configuration (as a function of the type of parameters and/or sub-parameters used, for example). This detection can also correspond to the identification of the design level and/or of the hierarchical scale of the configuration elements corresponding to variables to be evaluated in the considered candidate configurations.

A person skilled in the art will easily understand that the invention is not limited to a first GEM5-type evaluation tool and a second VPSim-type evaluation tool, and that other types of evaluation tools can be used, such as, for example, Virtualizer, Vista or any other functional level simulator. RTL level simulator type evaluation tools, such as ModelSim/Questa, can be used, for example, for a more accurate evaluation. Other simulators such as McPat can be used to evaluate the surface area or the energy consumption or thermal aspects. Functional simulator-type evaluation tools can be used to simulate the RTL code, and post-synthesis or post-physical implementation simulator-type evaluation tools (or Layout tools, relating to post-implementation obtained after placement and routing, for example) can be used to simulate, for example, the “netlist” generated by the compilation of the circuit, potentially with technological information allowing the consumed energy to be provided. Other evaluation tools such as, for example, “Cadence: First Encounter Design Exploration and Prototyping” or “Synopsys: Fusion Compiler” or “Synopsys: IC Compiler II”, can be used to simulate a circuit, with a circuit description that is fairly close to the end of the design flow.

Advantageously, during the same optimization iteration, each candidate configuration Gₙ can be associated with a number Jₙ of evaluation tools Oₘ from among the M tools. Each number Jₙ, associated with each given candidate configuration Gₙ, is an integer ranging between 1 and M.

The initialization block 142 can be configured to perform, for each of the candidate configurations Gₙ, a conversion (also called a “transformation”) of at least a portion of the candidate configuration Gₙ into a number Jₙ of target input files that can be understood (i.e., are readable and/or decipherable) by each of the Jₙ considered evaluation tools Oₘ (i.e., intended to evaluate the candidate configuration), respectively. The input file of an evaluation tool is a description file with a structure adapted to the evaluation tool and comprising a set of values for the associated input quantities Eₘ.

Advantageously, for a given candidate configuration Gₙ and an associated evaluation tool Oₘ, the initialization block 142 can be configured to convert this configuration into a number Hₙ of understandable target input files, each relating to a configuration instance to be evaluated.

An input file for an evaluation tool Oₘ can be generated based on the conversion of one or more selected configuration elements (parameters and/or sub-parameters) of the considered candidate configuration Gₙ into input quantity values Eₘ (target input quantities) of the evaluation tool Oₘ to which the configuration (or instance) is intended to be applied. The conversion of at least a portion of each candidate configuration into input quantity values Eₘ allows the candidate configuration to be adapted to the target format of the input file of the evaluation tool to which it is applied.

In some embodiments, such a conversion can be performed using one or more conversion registers R_{T} associated with the evaluation tools Oₘ The one or more conversion registers R_{T} can include, for each evaluation tool Oₘ, transcription elements corresponding to the target format of the considered evaluation tool, such as a Python script, a JSON file or an XML file, for example. The transcription elements to be used can be selected as a function of the candidate configuration Gₙ to be evaluated and of the evaluation tool Oₘ to which it is to be applied. For example, and without limitation, a transcription element can be selected based on the type of considered configuration elements, or even on the detected architectural hierarchical scale. Thus, a transcription element associated with a selected evaluation tool Oₘ to be executed can be applied to each candidate Gₙ configuration to which an evaluation tool is to be applied in order to generate an input file with a format adapted to the considered evaluation tool Oₘ. For example, and without limitation, for a VPSim simulator-type evaluation tool, the input files can be determined using a Python script (as a transcription element) in order to generate a hardware platform adapted to the VPSim simulator (for example, in terms of the number of cores, type, of memory parameters, of NoC parameters, etc.). Dynamically (or automatically) filling the Python script feeds the VPSim simulator by transcribing the parameters and sub-parameters of one or more given configurations.

The conversion operations implemented by the initialization block 142 improve the efficiency of the evaluation of the different candidate architectures and thus enable optimized architectures to be obtained more quickly, with greater flexibility, and automatically.

The initialization block 142 can include the steps of receiving (or determining) the candidate configurations Gₙ to be evaluated, of selecting an evaluation tool Oₘ for each candidate configuration Gₙ to be evaluated, and, for each evaluation tool Oₘ selected for a candidate configuration Gₙ:
selecting the configuration elements (corresponding to values of the parameters and/or sub-parameters) to be converted into target input quantity values Eₘ associated with the evaluation tool selected for the candidate configuration Gₙ;
determining at least one transcription element associated with the considered evaluation tool Oₘ; and
applying the transcription element to the selected elements of the candidate configuration Gₙ, which provides the target input quantity values Eₘ associated with the evaluation tool selected for the configuration.

For example, and without limitation, for each evaluation tool Oₘ, the elements of a candidate configuration Gₙ to be converted can be identified from a parameter/tool correspondence table.

In some embodiments, the conversions implemented by the initialization block 142 can be specific to each optimization iteration (i.e., to the determined candidate configurations Gₙ and to the selected evaluation tools Oₘ).

In some embodiments, the evaluation step 140 comprises a control block 144 configured to implement automatic or dynamic control (also called “management”) of the evaluation tools Oₘ used to evaluate the candidate configurations Gₙ.

As used herein, the term “control” refers to the implementation of a plurality of actions on one or more evaluation tools in response to a specific condition. An action associated with an evaluation tool refers to an action performed by the control block 144, using an input file of the evaluation tool. Such a specific condition can be, for example, and without limitation, a command, sending a request, detecting an instruction or implementing a specific action, etc.

In particular, the control block 144 is configured to trigger (or implement), for each evaluation tool Oₘ from among the M selected tools, one or more executions of the considered evaluation tool to evaluate each of the considered candidate configurations Gₙ by means of a selected tool. In particular, the control block 144 can be configured to trigger the executions of the considered evaluation tools in order to evaluate the considered configuration instances. The executions by the different evaluation tools can be triggered independently of each other or can be dependent on each other. The executions by the different evaluation tools also can be triggered simultaneously (i.e., at the same time), synchronously, successively (one after the other) and/or sequentially (i.e., according to a predefined sequence).

The order for triggering the different evaluation tools and/or the specific evaluation order for each of the candidate configurations can be predefined, for example, using a trigger file.

The initialization block 142 can be configured to generate the trigger (or control) file for executing the different considered evaluation tools Oₘ, for example, according to the different levels and/or the different scales of the configurations.

In particular, the control block 144 can be configured to trigger, for a given evaluation tool, one or more iterations of the execution of the evaluation tool (the execution is then referred to as an “iterative execution”). Thus, for each iterative execution, an execution of the evaluation tool is triggered for an analysis (or evaluation) of a specific configuration instance of a candidate configuration by the evaluation tool. The execution of the evaluation tool is repeated multiple times (with each repetition corresponding to an iteration), until a condition, called “stop condition”, is confirmed (i.e., met).

During an iterative execution of the evaluation tool applied to an instance of a candidate configuration Gₙ, the evaluation tool Oₘ can be configured to analyze a specific element or value of a variable to be evaluated from a list V associated with the evaluated candidate configuration.

In some embodiments, the control block 144 can be configured to trigger a first series of executions of the first evaluation tool O₁ (the first series of executions corresponds to a number of iterative executions of the first evaluation tool O₁). During the first series of executions, the first evaluation tool O₁ is applied to at least one candidate configuration (for example, the candidate configuration G₁) defined according to a first hierarchical scale, in accordance with a first design level.

The control block 144 also can be configured to trigger a second series of executions of the second evaluation tool O₂ (the first series of executions corresponds to a number of iterative executions of the second evaluation tool O₂). During the second series of executions, the second evaluation tool O₁ is applied to at least one candidate configuration (for example, the candidate configuration G₂) defined according to the first hierarchical scale or according to a second hierarchical scale, in accordance with the first design level or a second design level.

According to some embodiments, the second series of executions can be triggered as a function of the first series of executions. For example, and without limitations, the second series of executions of the second evaluation tool O₂ can be triggered in response to the completion of all the executions of the first series of executions of the first evaluation tool O₁. Alternatively, at least one iterative execution of the second evaluation tool O₂ can be triggered sequentially, or synchronously, in relation to an iterative execution of the evaluation tool O₁. In some embodiments, an iterative execution of the second evaluation tool O₂ can be triggered each time an execution of the first series of executions ends, or each time an execution of the first series of executions starts.

In some embodiments, the control block 144 also can be configured to store the analysis results of at least one tool from among the M selected evaluation tools Oₘ, by saving them in a memory. In particular, such storage can be implemented for each iterative execution or following several iterations (for example, the last iteration) of a series of executions. Furthermore, such storage can involve storing at least one output quantity Sₘ output from a considered evaluation tool Oₘ.

In some embodiments, the control block 144 can be configured to use analysis results from the first evaluation tool O₁ for one execution or a series of executions of the second evaluation tool O₂.

For example, and without limitations, the control block 144 can be configured to inject (or transmit) at least one output quantity S₁ output from the first evaluation tool O₁, for each iterative execution or after several iterative executions (for example, after the last iteration of the implemented series of executions), into the input file of the second evaluation tool O₂ as one or more input quantity values E₂.

The control block 144 also can be configured to inject values of elements of the candidate configuration G₁ applied to the first evaluation tool O₁, as a function of the analysis results of the first evaluation tool O₁, obtained for each iterative execution or after several iterative executions of the first series of executions, into the input file of the second evaluation tool O₂ as one or more input quantity values E₂.

Such injections of values can be applied, for example, for each iterative execution of the second evaluation tool or for the first iterative execution of the second series of executions of the second evaluation tool.

Advantageously, such elements to be injected (i.e., at least a portion of an analyzed candidate configuration and/or at least one output quantity output from an evaluation tool) notably can be extracted from the elements stored by the control block 144.

Advantageously, the control block 144 can be configured to convert the elements to be injected (at least one value of stored output quantities S₁ and/or an analysis result of at least one evaluated instance of the first candidate configuration G₁ by said first evaluation tool O₁) into the format of the target input file of the second evaluation tool O₂, i.e., into one or more input values E₂ of the target input file of the second evaluation tool O₂.

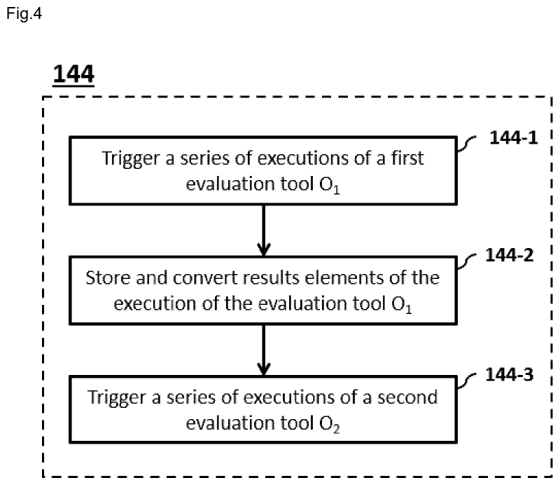

FIG. 4 schematically shows an example of the control of at least two evaluation tools O₁ and O₂ by the control block 144 in the step 140 of evaluating the candidate configurations Gₙ of the determination method, according to some embodiments of the invention.

As illustrated in FIG. 4, the control block 144 can be configured to trigger one or more executions 144-1 of the first evaluation tool O₁, and can be configured to store and convert 144-2 elements derived from the results of executing this evaluation tool O₁. The control block 144 can then trigger one or more executions 144-3 of the second evaluation tool O₂, using the previously stored and converted elements. The executions 144-3 also can be triggered in response to the conversion and/or the storage 144-2 of the result elements to be injected.

In some embodiments, the plurality of evaluation tools Oₘ can include a third evaluation tool O₃. The third evaluation tool O₃ can be configured to analyze, in accordance with an equivalent design level, candidate configurations defined according to an architecture scale similar to the configurations analyzed by the first evaluation tool O₁, for example. For example, and without limitation, the third evaluation tool O₃ can be selected to analyze the first candidate configuration G₁ of the plurality of N generated configurations. The control block 144 advantageously can be configured to additionally trigger one or more executions of the third evaluation tool O₃, at the same time as triggering executions 144-1 of the first evaluation tool O₁. The control block 144 thus can be configured to store and convert elements derived from the results of executing the evaluation tool O₃, and then to trigger the executions 144-3 of the second evaluation tool O₂, using the previously stored and converted elements derived from the analysis results of the first evaluation tool O₁ and of the third evaluation tool O₃.

According to some embodiments, the execution time t₁ of an iteration of the first evaluation tool O₁ for analyzing a configuration can be different from the execution time t₃ of an iteration of the third evaluation tool O₃ for analyzing the same and/or another configuration. For example, the execution time t₁ can be significantly shorter than the execution time t₃. Thus, in some embodiments, the control block 144 can be configured to trigger the executions 144-3 of the second evaluation tool O₂, in response to the conversion and/or the storage 144-2 of the result elements to be injected, derived from the analysis results of the evaluation tool with the longest execution time.

The evaluation step 140 comprises a stop block 146 (also called “iteration stop management block”) for the selected evaluation tools Oₘ.

The stop block 146 can be configured to stop the iterative executions of at least one of the tools of the M selected evaluation tools Oₘ, in response to the confirmation of a stop criterion.

Such a stoppage of the iterative executions of an evaluation tool (or an interruption in the execution) induces, while the evaluation tools Oₘ are controlled, an evaluation failure of at least one instance of a candidate configuration Gₙ scheduled to be evaluated by the evaluation tool Oₘ (i.e., the one or more instances that have not been evaluated due to the iterations being stopped).

It should be noted that, for a candidate configuration Gₙ, stopping the iterative executions of an evaluation tool Oₘ, in order to evaluate a number Hₙ of configuration instances, results in the total number of iterations Hi that are actually implemented being strictly less than the number Hₙ of iterations scheduled when the considered iterative execution was triggered.

This results in a failure to analyze instances that have not been analyzed (i.e., not processed), after iterative executions have stopped.

The non-analyzed candidate configuration instances Gₙ then can be considered to be useless for determining optimized architecture configurations Gₒₚₜ. Such a failure to analyze (also called “execution deviation”) improves the efficiency of evaluating the different candidate architectures and allows optimized architectures to be obtained more quickly without unnecessary analysis of configurations, optionally by testing more relevant candidate configurations. The interruption of an evaluation tool Oₘ that results in a failure to analyze certain candidate configuration instances Gₙ is possible by virtue of the confirmation of at least one stop criterion (also called “interruption criterion”).

Furthermore, the failure to analyze certain instances of a first candidate configuration G₁ defined according to a first architecture scale, in accordance with a first design level, can result in a failure to analyze some or all of the instances of at least one second candidate configuration G₂. Such a failure to analyze may be possible, for example, in the event that the second candidate configuration G₂ is, for example, a sub-configuration of the first candidate configuration G₁ whose analysis was interrupted. The second candidate configuration G₂ then can be defined according to a second hierarchical scale and be analyzed in accordance with the first or second design level. The accumulation of failures to analyze instances of candidate configurations significantly speeds up the effective analysis time of the step 140 of evaluating candidate configurations Gₙ, thereby significantly saving on computing resources.

In some embodiments, for an evaluation tool and a given candidate configuration, it is possible to confirm whether a stop criterion has been met at the end of one or more iterative executions of a tool.

Advantageously, the stop criteria associated with each considered evaluation tool for the evaluation of a given candidate configuration can differ from one another. A stop criterion for one tool can also depend on the iterative executions of another tool.

If the stop criterion is not considered to be met, the iterative executions of the evaluation tool continue. Thus, if the stop criterion is not confirmed during a series of executions of an evaluation tool, a new iterative execution of the considered evaluation tool is implemented (the execution is repeated).

It should be noted that at the end of an iterative execution, if the stop criterion is not considered to be met, the number of iterations Hi actually implemented then can be equal to the number Hₙ of iterations planned when the considered iterative execution was triggered.

If the stop criterion is considered to have been met, the execution of the evaluation tool applied to a candidate configuration is stopped.

In some embodiments, the stop block 146 can be configured to apply a temporary interruption (also called “pause”) to the iterative executions of at least one of the selected M evaluation tools Oₘ, in response to the confirmation of a first predefined criterion, such as a pause criterion. In some embodiments, the control block 144 can be configured to trigger the continuation of the paused iterative executions in response to the confirmation of a second predefined criterion, such as a resumption criterion. If such a resumption criterion is not confirmed, the paused iterative executions can be considered to be stopped.

It should be noted that, for a candidate configuration Gₙ, the result of resuming the iterative executions of an evaluation tool Oₘ after an interruption is that the total number of iterations, denoted Hⱼ, actually implemented at the end of the iterative execution, is strictly greater than the number Hᵢ of iterations implemented until the iterative execution is interrupted upon confirmation of the stop criterion.

Such a pause in the iterative executions of the same tool evaluating a given candidate configuration can be applied, for example, to allow the control block 144 to trigger the evaluation of the same configuration with another tool, or of another candidate configuration with the same tool or another tool.

For example, and without limitation, the control block 144 can be configured to trigger iterative executions of a first evaluation tool O₁. This initial triggering of iterative executions can be implemented, for example, in response to the generation of an input file of the first evaluation tool O₁. The stop block 146 can be configured to then pause these iterative executions of the first evaluation tool O₁. The iterative executions can be paused, for example, in response to the control block 144 triggering one or more executions of the second evaluation tool O₂. The control block 144 can be configured to then trigger the continuation of the previously paused iterative executions of the first evaluation tool O₁. This resumption of execution (or second triggering) can be implemented, for example, in response to the conversion and/or the storage of analysis results from the second evaluation tool O₂ to be injected, as one or more new input quantity variables Hᵢ, into the input file, and then modified for the paused iterative executions of the first evaluation tool O₁. Such an injection notably allows the input values of the paused first evaluation tool O₁ to be refined, by providing it with more inputs, modifying its inputs (i.e., parameters and/or sub-parameters), etc.

By way of a non-limiting example, the execution time t₁ of the first evaluation tool O₁ can be significantly greater than the execution time t₂ of the second evaluation tool O₂. The iterative executions of the first evaluation tool O₁ can be implemented in order to very precisely analyze a candidate configuration, while the iterative executions of the second evaluation tool O₂ can be implemented in order to less precisely, but very quickly, analyze this candidate configuration. These iterative executions of the first evaluation tool O₁ can be triggered and then paused, for example, in response to the analysis of results derived from the execution of the first evaluation tool O₁. These initial results can be considered to be unfavorable, in this case corresponding to a pause criterion. The paused iterative executions of the first evaluation tool O₁ can be triggered again following the implementation of the iterative executions of the second evaluation tool O₂. In particular, the second triggering of the first evaluation tool O₁ can be implemented in response to the analysis of results derived from the execution of the second evaluation tool O₂. For example, the second triggering of the first evaluation tool O₁ can be implemented if the evaluation results of the second evaluation tool O₂ confirm the determination of favorable intermediate results, in this case corresponding to a resumption criterion.

Such a pause in the iterative executions of a tool thus allow the evaluation efficiency of the different candidate architectures to be drastically improved, which considerably saves on computing resources, yielding a better eco-design for the integrated circuit to be designed.

In some embodiments, the control block 144 can be configured to trigger all iterative executions of an evaluation tool Oₘ a second time, in response to the confirmation of another predefined criterion, such as a repetition criterion.

Such a repetition of iterative executions of the same tool evaluating a given candidate configuration can be implemented, for example, in response to the analysis, the conversion and/or the storage of evaluation results of the tool or of another evaluation tool. Such a repetition can be performed in response to the injection of analysis results as new input values into the input file associated with the given candidate configuration.

Throughout the remainder of the description, reference is only made to the concept of a “stop criterion”. However, a person skilled in the art will easily understand that the description of the following embodiments, associated with the use of the “stop criterion”, similarly applies to the “pause criterion”, the “resumption criterion”, and the “repetition criterion”.

In some embodiments, the stop criterion can be defined as a function of the execution time of an iterative execution tₘ or of the execution time resulting from the plurality of iterative executions and/or a number of executed iterations, of a tool, and/or of the analysis of a considered configuration. For example, the stop criterion may be considered to be met if the exploration time limit t_{max_m} is reached (i.e., the resulting execution time has elapsed, with the resulting execution time then being greater than or equal to the exploration time limit t_{max_m}).

In some embodiments, the stop criterion can be defined based on a comparison of different output values Sₘ returned in response to the execution of a given evaluation tool Oₘ, for each iterative execution, and/or in response to several iterative executions of a given evaluation tool Oₘ of a series of executions, for example, after the last iteration of an iterative execution. Such a comparison can be implemented in order to determine at least one optimal value of a specific variable from the list V of variables associated with a defined candidate configuration.

In other words, at least some of the instances of the same candidate configuration Gₙ can be evaluated and compared with each other in order to analyze the effect of the different variable values on the candidate configuration Gₙ.

Similarly, the stop criterion can be defined based on the comparison of different output values Sₘ returned in response to the execution of several given evaluation tools Oₘ.

In some embodiments, the stop criterion can relate to the evaluation of one or more objective and/or constraint functions relative to determined circuit optimization criterion values.

An objective and/or constraint function of a set (or list) F in the architecture exploration space is defined in order to evaluate one or more circuit optimization criteria associated with an integrated circuit configuration to be designed. An objective and/or constraint function then corresponds to a mathematical formulation associated with one or more objectives and/or constraints of the integrated circuit to be designed.

A plurality of circuit optimization criteria C_{q} exist. The index “q” associated with different optimization criteria is thus an integer ranging between 1 and the value of an integer greater than or equal to 3. In some embodiments, the optimization criteria can include the following three main optimization criteria:
a first main optimization criterion C₁ of the circuit corresponding to the computing performance of the integrated circuit, which can be defined, for example, by a number of floating-point operations per second expressed as FLOPS, a temporal datum of the integrated circuit, such as a latency (in seconds) or an operating frequency (in Hertz), or even a measurement of a memory size (in number of bits or bytes);
a second main optimization criterion C₂ of the circuit corresponding to the energy consumption of the integrated circuit; and
a third main optimization criterion C₃ of the circuit corresponding to the surface area of the integrated circuit.

Advantageously, other circuit optimization criteria C_{q} can be defined, such as the price of the circuit, the environmental footprint of the circuit (such as the carbon footprint, for example), the manufacturing time of the circuit, the security level of the circuit, etc.

For example, and without limitation, the set F of objective and/or constraint functions can include a first, a second and a third objective function, F₁, F₂ and F₃, respectively associated with the first, the second and the third main optimization criteria, C₁, C₂ and C₃, of the circuit. The first objective function F₁ can be an argument of the maxima function (or Argmax) of the computing performance of the integrated circuit C₁. The second objective function F₂ and the third objective function F₃ then can be an argument of the minima function (or Argmin) of the energy consumption of the integrated circuit C₂ and an argument of the minima function of the surface area of the integrated circuit C₃. The arguments of the maxima and minima functions refer to the functions for determining the one or more possible minimum and maximum values, respectively, of a variable represented by a set of data.

In particular, it should be noted that an objective function in the list F is a function that seeks to minimize or maximize a criterion expressed as a circuit optimization objective. A constraint function in the list F is a function that seeks to comply with a constraint of the integrated circuit to be designed. For example, and without limitation, a constraint function then can be an inequality function between several parameters in the list P and/or sub-parameters in the list Lₙ.

For the evaluation of the stop criterion, the stop block 146 also can be configured to determine two or more values of the circuit optimization criterion C_{q} based on analysis results of at least one candidate configuration obtained by executing the evaluation tools via the control block 144.

Two optimization criteria from among all the optimization criteria of the circuit to be determined can be selected from among conflicting optimization criteria characterizing the integrated circuit to be designed, i.e., selected from among at least one main computing performance optimization criterion, one main energy consumption optimization criterion and one main integrated circuit surface area optimization criterion.

For example, and without limitation, the value of the computing performance C₁ can be obtained based on the estimation of performance determined by a first evaluation tool O₁ (for example, the VPSim simulator) or by a second evaluation tool O₂ (for example, the GEM5 simulator).

According to some embodiments, at least one value of a circuit optimization criterion C_{q} to be determined can be computed using one or more analytical formulas (or analytical functions). Such an analytical formula can use at least one or more evaluation results of one or more candidate configurations by at least one evaluation tool as input parameters.

Advantageously, such input parameters of an analytical formula can include at least one item of information related to the structure of the integrated circuit to be designed and/or one item of information related to the operating activity of the integrated circuit to be designed. For example, and without limitation, information referred to as structural information can correspond to a number or a type of constituent elements (for example, cores) of an integrated circuit. Information referred to as activity information can correspond to a number or a type of access to memory or to a constituent element of the integrated circuit, to a number or a type of stress on a constituent element of the integrated circuit or to a chain of constituent elements of the integrated circuit, to a number or a type of operations performed by the integrated circuit, etc. The type of activity information can depend on the design level of the integrated circuit. For example, the computation latency of a constituent element of the circuit can be activity information and can be used to compute a more overall latency or a quantity related to energy consumption using an analytical formula.

Advantageously, such input parameters of an analytical formula can also include technological information that is determined based on one or more technological databases including data for constituent elements of the circuit that can be manufactured according to given integrated circuit design technology.

Advantageously, information (structural, activity and/or technological) can correspond to configuration elements (parameters and/or sub-parameters, or constituent elements) of the evaluated candidate configurations and/or one or more obtained valuation results, i.e., one or more values of output quantities Sₘ derived from at least one of the evaluation tools Oₘ.

In some embodiments, the step of determining the value of a circuit optimization criterion C_{q} can be performed using a function register. The function register is associated with the analytical formulas to be applied to the information (structural, activity and/or technological) in order to compute a value of a circuit optimization criterion C_{q}.

For example, an analytical function can include a sum of parameters, a division, a subtraction, and/or a multiplication, etc.

For example, and without limitation, in order to determine a value of the third main optimization criterion C₃ of the circuit, corresponding to the surface area of the integrated circuit, an analytical function can be a sum taking the sum of the surface areas of the circuit elements as arguments. In order to determine a value of the second main optimization criterion C₂ of the circuit, corresponding to the energy consumption of a computation element of the integrated circuit, an analytical function can be a multiplication taking the number of activations of each operation and their average energy consumption as arguments.

It should be noted that a value of a circuit optimization criterion C_{q}, defined from among all the circuit optimization criteria to be determined, can be obtained directly based on the values of output quantities Sₘ following the analysis of a candidate configuration by a considered evaluation tool Oₘ. The evaluation tool Oₘ can then use technological databases for its internal operation. In this case, the value of the circuit optimization criterion C_{q} is not obtained by an analytical function executed following the analysis by the evaluation tool.

In the stop block 146, the selection, from the function register, of the one or more analytical formulas to be applied can be made based on the circuit optimization criterion C_{q} to be determined.

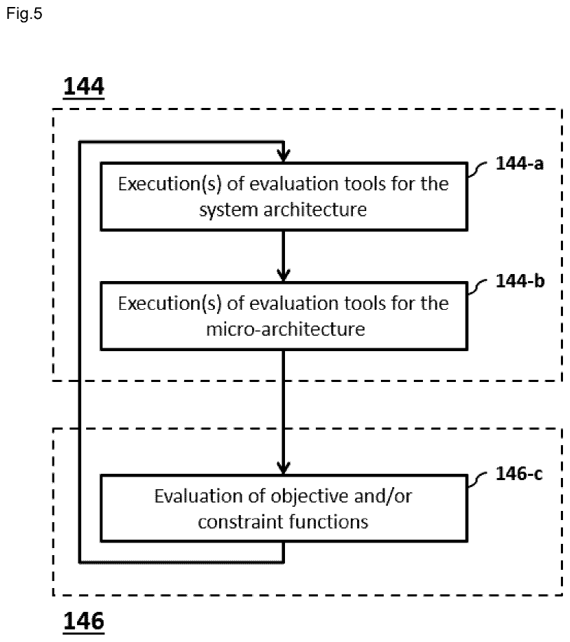

FIG. 5 schematically shows the control block 144 and the stop block 146, according to some embodiments of the invention.

As illustrated in FIG. 5, the control block 144 can be configured to trigger one or more executions 144-a of at least one first evaluation tool adapted to evaluate configurations relating to the system architecture, and to trigger one or more executions 144-b of at least one second evaluation tool adapted to evaluate microarchitecture configurations. Furthermore, the stop block 146 can be configured to implement an evaluation 146-c of one or more objective and/or constraint functions associated with configurations to be evaluated.

In some embodiments, in the control block 144 and/or in the stop block 146, the evaluation results generated by the plurality of evaluation tools Oₘ and/or the values of the circuit optimization criteria C_{q} associated with each candidate configuration Gₙ can be recorded (i.e., stored) in a candidate configuration data memory.

Advantageously, in order to evaluate a stop criterion relating to the evaluation of objective and/or constraint functions, the stop block 146 can be configured to evaluate values of optimization criteria in response to the storage of the elements associated with these criteria (notably derived from the analysis results of one or more evaluation tools). Thus, the evaluation of stop criteria can be continuously performed when controlling the different evaluation tools Oₘ.

In some embodiments, the stop block 146 can be configured to stop the executions of the first evaluation tool O₁ triggered by the control block 144 in response to the confirmation of at least one stop criterion. The control block 144 (and/or the stop block 146) can be configured to store and convert elements derived from the execution results after the evaluation tool O₁ has been stopped. The control block 144 can be configured to then trigger one or more executions of the second evaluation tool O₂, using the stored and converted elements, and in response to the evaluation tool O₁ being stopped by the stop block 146.

The dynamic use of the analysis results of candidate configurations between different tools in the control block 144 and the evaluation of the optimization criteria in the stop block 146 allows fast and complete multi-level and/or multi-scale evaluation of the candidate configurations for different criteria. In particular, the configuration of the control block 144 allows traces to be retrieved from different evaluation tools (for example, simulators) and allows them to be injected, in real time, into a second evaluation tool (for example, a simulator), or other evaluation tools, for the mixed and dynamic evaluation of several parameters. Furthermore, the configuration of the stop block 146 allows a simulation to be stopped at any time when the simulators are being executed according to a specified stop criterion, and allows the obtained results to be returned. Stopping the simulators according to the embodiments of the invention allows a time/accuracy compromise to be applied with respect to the evaluation of candidate configurations.

For example, and without limitation, one or more given candidate configurations can be evaluated by the GEM5 simulator in order to obtain a very accurate estimate of the values of the performance of computations C₁ associated with these configurations. However, the very high analysis (i.e., simulation) time of these configurations by the GEM5 simulator can result in an overall evaluation time for all the candidate configurations of the same optimization iteration. Furthermore, one or more given candidate configurations can be evaluated by the VPsim simulator in order to obtain a less accurate estimate of the values of the performance of computations C₁ associated with these configurations, but according to the very short analysis (i.e., simulation) time of these configurations, hastening the overall evaluation of all the candidate configurations of the same optimization iteration. Thus, such simulators can be executed at the same time, and the evaluation of the optimization criteria in the stop block 146 can use either of the two simulators (GEM5 or VPsim) depending on the availability of the evaluation results. In particular, the evaluation of optimization criteria, and therefore the evaluation of at least one candidate configuration, can be updated in response to the storage of the results of a simulator.

For example, and without limitations, in order to obtain an estimate of the values of the performance of computations C₁ associated with one or more given candidate configurations, the stop block 146 can also combine the evaluation results derived from the Arm Fast models (which are not related to the execution time) with the evaluation results from the VPSim simulator. Such a combination allows a dynamic estimation to be provided for values of the performance of computations C₁ by focusing on a particular part of the hardware architecture (or by processing it individually) via the model (or method) known as ROI (Region Of Interest).

According to another non-limiting example, in order to obtain an estimate of values of energy consumption C₂ associated with one or more given candidate configurations, the stop block 146 can combine the evaluation results of these configurations by GEM5 and VPsim (interconnection access or memory obtained) with the consumption of an access operation (read, write, etc.). The consumption of an access operation can be obtained based on data provided by a computing resource supplier (IP “Intellectual Property” block), RTL simulations of an architectural model (memory models, IP models simulated in tools such as Prime Time PX by Synopsys), data related to the technology node, or even high-level simulations performed using dedicated simulators such as, for example, CACTI for cache memories or even McPat for the entire system.

In order to obtain an estimate of values of the criterion C₃ (integrated circuit surface area) for at least one given candidate configuration, the stop block 146 can combine available data (for example, derived from a computing resource provider), evaluation results of RTL syntheses of an architectural model (for example, Design Compiler by Synopsys), surface area models available in McPat, or even high-level simulations performed using dedicated simulators (for example, CACTI for cache memories).

According to some embodiments, step 160 of the determination method can use the results of the evaluation of the stored candidate configurations Gₙ and the evaluations of the values of optimization criteria in order to determine optimized configurations Gₒₚₜ.

In some embodiments, step 160 can include a sub-step of sorting and/or classifying evaluated candidate configurations Gₙ (or configuration instances). Such a sub-step can be performed (or executed) based on values of determined circuit optimization criteria C_{q} and/or on the evaluation of one or more objective and/or constraint functions relative to the values of determined circuit optimization criteria C_{q}. Such a sub-step also can be performed in order to retain the candidate configurations called “dominant configurations”. A dominant configuration refers to a candidate configuration defined in relation to at least one additional candidate configuration evaluated during the same iterative execution of a tool, the same optimization iteration and/or two different execution or optimization iterations. A dominant configuration has configuration evaluation results that lead to a better evaluation across all the objective and/or constraint functions compared to the evaluation across all the objective and/or constraint functions induced by the configuration evaluation results derived from an ancillary candidate configuration. Such a sub-step also can be performed in order to rank the evaluated candidate configurations, or only dominant configurations, as a function of the evaluation of one or more objective and/or constraint functions.

A person skilled in the art will easily understand that some steps or sub-steps of the method can be performed simultaneously, sequentially, successively, independently or non-independently, and/or in a different order, for example, in an order defined by the initialization of the implementation of the tools.

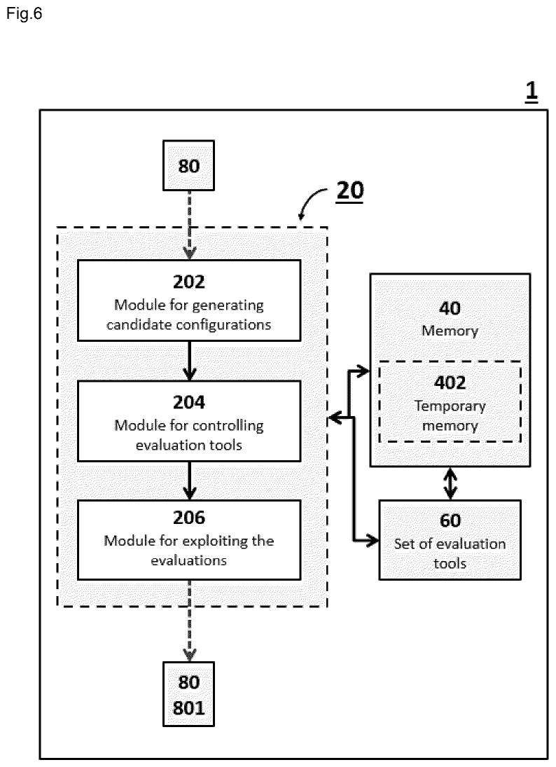

FIG. 6 shows an example of a system 1 for designing the hardware architecture of an integrated circuit in which the method for designing integrated circuit hardware architectures can be implemented.

The system 1 for determining (or designing) an integrated circuit hardware architecture comprises a device 20 for determining the hardware architecture configured to implement the method for determining integrated circuit hardware architectures. The determination system 1 further comprises a memory 40.

As shown in FIG. 6, the system 1 comprises a set 60 of available evaluation tools. The device 20 can include a module 202 configured to generate candidate configurations Gₙ, an evaluation module 204 configured to evaluate the candidate configurations based on selected evaluation tools Oₘ, and an exploitation module 206 configured to exploit evaluation results of candidate configurations in order to generate optimized configurations.

In particular, the evaluation module 204 (or management module, control module) can be configured to implement the different functional blocks associated with the evaluation of the candidate configurations Gₙ in the determination method.

In some embodiments, the memory 40 can include at least one conversion register R_{T} associated with the evaluation tools that can be used by the evaluation module 204 in order to select the transcription elements associated with the evaluation tools and convert elements of the candidate configurations.

The memory 40 can also include a temporary memory 402 configured to store at least a portion of the evaluation results delivered by the plurality of executed evaluation tools Oₘ and/or the circuit optimization criterion values C_{q} associated with candidate configurations. The use of a temporary memory 402 accelerates the exploration of the different multi-scale and/or multi-level architecture configurations in order to quickly and accurately generate an optimized integrated circuit.

In some embodiments, the system 1 can include one or more data input/output interfaces, such as human-machine interfaces 80 (HMIs). These human-machine interfaces can include one or more means for acquiring or transmitting information, such as input and control devices (for example, a microphone, a speaker, a keyboard) and/or one or more display devices (for example, a video screen, a touch screen, etc.). For example, and without limitation, the system 1 can include a human-machine interface 80 configured to acquire an architecture descriptor provided by a user of the system 1 in the form of a template of a computing architecture for defining the architecture exploration space.

In some embodiments, the system 1 can include a conversion tool 801 configured to convert the optimized configuration Gₒₚₜ into a hardware architecture description file (also called “hardware description file”) on the RTL defining the behavior of a circuit and which can be directly converted into combinational logic gates and sequential elements (flip-flops, etc.). A description of a hardware architecture on the RTL, known as low level, can be defined, for example, in a hardware description language (HDL) such as Verilog or VHDL.

The use of optimized configurations Gₒₚₜ by implementing the method for determining hardware architecture, according to the embodiments of the invention, allows multi-scale and/or multi-level management of the design of integrated circuit hardware architectures.

The set 60 of the determination system 1 can include evaluation tools that can be used according to different scales of architecture configurations or one or more constituent elements of an architecture configuration. Thus, the conversion and function registers can be adapted to the evaluation tools and to each of the different description levels of architecture configurations that can be used by the evaluation tools. Advantageously, some evaluation tools can be exploitable and used on a multitude of hardware architecture design levels.

A person skilled in the art will understand that the invention can be computer-implemented, in particular as a computer program comprising instructions for the execution thereof. The computer program can be stored on a processor-readable storage medium. The reference to a computer program that, when executed, performs any one of the functions described above is not limited to an application program running on a single host computer. On the contrary, the terms computer program and software are used herein in a general sense to refer to any type of computer code (for example, application software, firmware, microcode, or any other form of computer instruction) that can be used to program one or more processors to implement aspects of the techniques described herein. The computing means or resources notably can be distributed (“cloud computing”), optionally using peer-to-peer technologies.

The software code can be executed on any suitable processor (for example, a microprocessor) or processor core or a set of processors, whether provided in a single computing device or distributed among several computing devices (for example, as is optionally accessible in the environment of the device). The executable code of each program allowing the programmable device to implement the processes according to the invention can be stored, for example, in the hard disk or a read-only memory. In general, the one or more programs can be loaded into one of the storage media of the device before being executed. The central unit can control and direct the execution of the instructions or portions of software code of the one or more programs according to the invention, which instructions are stored in the hard disk or in the read-only memory or even in the other aforementioned storage elements.

The method for determining hardware architectures can be implemented on a distributed computing unit comprising a plurality of physical cores. The embodiments of the invention are particularly suitable for such a distributed implementation, as well as to porting on multi-core hardware technologies. The method for determining hardware architectures according to the embodiments of the invention can be implemented in computer code (which notably can be made up of a hardware abstraction language) in different languages, such as C, C++, Python, etc.

The invention is not limited to the embodiments and examples that are described above by way of non-limiting examples. The invention encompasses all the variants of embodiments that can be contemplated by a person skilled in the art. This listing of claims replaces all prior versions, and listings of claims in the application:

1. A method for determining a hardware architecture of an integrated circuit, the method being computer-implemented, the method comprising:
determining a plurality of candidate architecture configurations (Gₙ) corresponding to different hierarchical scales of the architecture of said integrated circuit to be designed, each candidate configuration (Gₙ) being defined by a set of configuration elements comprising at least one configuration element, each candidate configuration (Gₙ) being associated with a number (Hₙ) of instances (Gₙₕ) of the candidate configuration, each configuration instance corresponding to a combination of values of said configuration elements;
evaluating said plurality of candidate configurations (Gₙ) using at least two evaluation tools (Oₘ) selected from among a plurality of evaluation tools capable of performing a multi-level analysis of architecture design, each candidate configuration (Gₙ) being evaluated by at least one of said selected evaluation tools (Oₘ), the evaluation of a candidate configuration (Gₙ) by an evaluation tool comprising the iterative execution of the evaluation tool in order to evaluate one or more instances of said candidate configuration, the iterative execution of the tool comprising a number (Hᵢ) of iterations, each iteration corresponding to the evaluation of an instance of the candidate configuration by the evaluation tool,
the evaluation step providing an evaluation output relating to the execution of each of said at least two selected evaluation tools (Oₘ);
determining at least one optimized configuration of a hardware architecture of an integrated circuit (Gₒₚₜ) based on said evaluation output;
the method comprising automatic control of said at least two selected evaluation tools (Oₘ), said control comprising the control of at least one iterative execution of each evaluation tool for the evaluation of at least one candidate configuration (Gₙ);
the method comprising interrupting the iterative execution of an evaluation tool (Oₘ) associated with a candidate configuration, in response to the confirmation of a stop criterion;
the stop criterion being defined as a function of the execution time of an iterative execution and/or of an evaluation of at least one objective and/or constraint function relating to at least one optimization criterion, said at least one optimization criterion (C_{q}) being selected from among a computing performance criterion, an energy consumption criterion and/or a surface area criterion of said integrated circuit to be designed;
said stop criterion being further defined such that the total number of iterations (Hᵢ) of said iterative execution is strictly less than the number (Hₙ) of instances of the candidate configuration (Gₙ).

2. The method according to claim 1, wherein the evaluation step comprises resuming the iterative execution of a selected evaluation tool (Oₘ) after an interruption, in response to the confirmation of a resumption criterion, with the resumption criterion being defined as a function of said execution time of an iteration execution and/or of said evaluation of at least one objective function and/or of a constraint relating to said at least one optimization criterion, said resumption criterion being defined such that the total number of iterations (Hⱼ) of said iterative execution is strictly greater than the number of iterations (Hᵢ) implemented until the interruption

3. The method according to claim 1, wherein said plurality of candidate configurations (Gₙ) comprises at least one first candidate configuration (G₁) and one second candidate configuration (G₂), said second candidate configuration (G₂) being a sub-configuration of said first candidate configuration (G₁), said selected evaluation tools (Oₘ) comprising at least one first evaluation tool (O₁) for evaluating said first candidate configuration (G₁) and one second evaluation tool (O₂) for evaluating said second candidate configuration (G₂), the stop criterion for interrupting the iterative execution of said second evaluation tool (O₂) being confirmed in response to the interruption of the iterative execution of said first evaluation tool (O₁).

4. The method according to claim 1, wherein the evaluation of an instance of a candidate configuration (Gₙ) by an evaluation tool comprises:
an analysis of an instance of said architecture configuration by the evaluation tool in response to the reception of input quantity values (Eₘ) associated with the configuration instance; and
determining a set of output quantity values (Sₘ) relating to the result of the analysis of the configuration instance by said evaluation tool.

5. The method according to claim 4, wherein said evaluation step comprises, for each candidate configuration (Gₙ) to be evaluated, the conversion of at least a portion of said candidate configuration (Gₙ) into input quantity values (Eₘ) and the generation of an input file (Fₘ) associated with one of said evaluation tools (Oₘ) selected so as to evaluate said candidate configuration (Gₙ), said input file (Fₘ) comprising said input quantity values (Eₘ).

6. The method according to claim 3, wherein said plurality of candidate configurations (Gₙ) comprises at least one first candidate configuration (G₁) and one second candidate configuration (G₂), said selected evaluation tools (Oₘ) comprising at least one first evaluation tool (O₁) for evaluating said first candidate configuration (G₁) and one second evaluation tool (O₂) for evaluating said second candidate configuration (G₂), and wherein each iteration of an iterative execution of an evaluation tool provides at least one output quantity value, the iterative execution of the first evaluation tool (O₁) for evaluating said first candidate configuration (G₁) comprising, in response to an iterative execution of said first evaluation tool (O₁), storing said at least one output quantity value (S₁), and triggering at least one iterative execution of said second evaluation tool (O₂) for evaluating said second candidate configuration (G₂).

7. The method according to claim 4, wherein at least one input quantity value (E₂) of said input file of said second evaluation tool (O₂) is defined based on the conversion of said at least one stored output quantity value (S₁).

8. The method according to claim 1, wherein the evaluation step comprises simultaneously triggering at least one iterative execution of at least two of said selected evaluation tools (Oₘ).

9. The method according to claim 1, wherein said stop criterion is defined as a function of the execution time of at least one of the iterative executions of a given evaluation tool (Oₘ), the stop criterion being met if said execution time reaches a predefined maximum execution time.

10. The method according to claim 1, wherein an evaluation tool (Oₘ) from said plurality of evaluation tools is an evaluation tool selected from among an architecture configuration simulator, an architecture compilation tool, a consumption evaluation tool, a tool based on the use of a database, and a tool based on the use of a memory of candidate configuration data.

11. An integrated circuit hardware architecture obtained by implementing the method according to claim 1.

12. A method for designing an integrated circuit comprising an implementation of an integrated circuit based on the integrated circuit hardware architecture of claim 11.

13. A non-transitory computer-readable storage medium having stored thereon computer programming code instructions, which when implemented on a computer, execute the method according to claim 1.
